(19) United States
(12) Patent Application Publication
(10) Pub. No.: US 2008/0237727 A1
(43) Pub. Date: Oct. 2, 2008

(54) SEMICONDUCTOR DEVICE AND METHOD FOR MANUFACTURING A SEMICONDUCTOR DEVICE

(75) Inventors: Reika ICHIHARA, Kanagawa-ken (JP); Yoshinori Tsuchiya, Kanagawa-ken (JP); Masato Koyama, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/965,563

(22) Filed: Dec. 27, 2007

(30) Foreign Application Priority Data
Mar. 28, 2007 (JP) 2007-85709

(51) Int. Cl. H01L 27/092; H01L 21/8238

(52) U.S. Cl. 257/369; 438/231; 257/E21.632; 257/E27.062

(57) ABSTRACT

The present invention provides a CMIS device that achieves a low threshold voltage by use of a metal gate superior in the resistance to annealing in a reducing atmosphere. The CMIS device includes a substrate, PMISFET and NMISFET. THE PMISFET includes: an N-type semiconductor layer formed on the substrate; first source/drain regions formed in the N-type semiconductor layer; a first gate insulating film formed on the N-type semiconductor layer between the first source/drain regions; a carbon layer formed on the first gate insulating film and having a thickness of 5 nanometers or smaller; a first gate electrode formed on the carbon layer and including a metal.

### CROSS-REFERENCE TO RELATED APPLICATIONS

This application is based upon and claims the benefit of priority from prior Japanese Patent Application No. 2007-85709, filed on Mar. 28, 2007 in Japan, the entire contents of all of which are incorporated herein by reference.

### BACKGROUND OF THE INVENTION

1. Field of the Invention

The present invention relates to a semiconductor device and method for manufacturing a semiconductor device.

2. Description of the Related Art

In general, growing numbers of attempts to increase the integration level and performance of a semiconductor device as a constituent of electronic equipment have been made with an increase of the needs for electronic equipment having a smaller size and higher performance. In the case where such semiconductor device is e.g. an MISFET (Metal-Insulator-Semiconductor Field Effect Transistor), it is required to reduce the thickness of the gate insulating film thereof for the purpose of making the circuit components finer. As for polycrystalline silicon gate electrodes, which have been used widely and frequently, even when they are used for a device having a gate length of 50 nanometers or smaller, enhancement of the performance cannot be achieved. With the current generation of the art, the equivalent SiO₂ film thickness of the gate insulating film is 2 nanometers or below, and therefore the reduction in gate capacity owing to the depletion of an interface of a polycrystalline silicon gate electrode is actualized.

The depletion of a gate electrode can be reduced by increasing an electric charge density in the electrode. However, the concentration of an impurity in silicon (Si) is up to 2×10²⁰/cm⁻² approximately. Also, in this case, the reduction in capacity corresponding to an equivalent SiO₂ film thickness of 0.5 nanometers is developed. The reduction in capacity becomes a serious problem for the generation of CMIS (Complementally Metal-Insulator-Semiconductor) technology, in which the equivalent SiO₂ film thickness of an insulating film is not more than 2 nanometers.

Hence, a metal gate technology using a metal as a material for gate electrodes attracts attention, which is disclosed in JP-A 2006-245324, for example). Metal has a high electric charge density as large as the density of atoms, and therefore when a metal is used for a gate electrode, the depletion of the gate electrode can be ignored.

### BRIEF SUMMARY OF THE INVENTION

The present invention provides a CMIS semiconductor device which achieves a low threshold voltage by use of a metal gate superior in the resistance to annealing in a reducing atmosphere.

According to a first aspect of the present invention, there is provided a semiconductor device comprising:

a substrate;

an N-type semiconductor layer formed on the substrate;

first source/drain regions formed in the N-type semiconductor layer;

a first gate insulating film formed on the N-type semiconductor layer between the first source/drain regions;

a carbon layer formed on the first gate insulating film and having a thickness of 5 nanometers or smaller;

a first gate electrode formed on the carbon layer and including a metal;

a P-type semiconductor layer formed on the substrate;

second source/drain regions formed in the P-type semiconductor layer;

a second gate insulating film formed on the P-type semiconductor layer between the second first source/drain regions; and

a second gate electrode formed on the second gate insulating film.

According to a second aspect of the present invention, there is provided a method for manufacturing a semiconductor device comprising:

forming a P-type semiconductor region and an N-type semiconductor region on a semiconductor substrate, the P-type and N-type semiconductor regions being isolated from each other;

forming a first dummy gate on the P-type semiconductor region and a second dummy gate on the N-type semiconductor region;

forming first source/drain regions in the P-type semiconductor region on opposite sides of the first dummy gate;

forming second source/drain regions in the N-type semiconductor region on opposite sides of the second dummy gate;

forming an insulating layer on side portions of the first and second dummy gates covering the first and second source/drain regions;

removing the first and second dummy gates thereby to form first and second grooves in the insulating layer;

forming first and second gate insulating films on bottom portions of the first and second grooves;

forming a carbon layer which covers a top of the second gate insulating film, but not a top of the first gate insulating film; and

forming first and second gate electrode materials including a metal on the first gate insulating film and carbon layer.

According to a third aspect of the present invention, there is provided a method for manufacturing a semiconductor device comprising:

forming a P-type semiconductor region and an N-type semiconductor region on a semiconductor substrate, the P-type and N-type semiconductor regions being isolated from each other;

forming a first gate insulating film on the P-type semiconductor region and a second gate insulating film on the N-type semiconductor region;

forming a carbon layer which covers a top of the second gate insulating film, but not a top of the first gate insulating film;

forming first and second gate electrode materials including a metal on the first gate insulating film and carbon layer;

etching the carbon layer and the gate electrode material, thereby to form a first gate electrode including the gate electrode material, and to form a second gate electrode including the gate electrode material and carbon layer; and

then, forming first source/drain regions in the P-type semiconductor region; and

forming second source/drain regions in the N-type semiconductor region.

### BRIEF DESCRIPTION OF THE SEVERAL VIEWS OF THE DRAWING

FIG. 1 is a sectional view of a CMIS semiconductor device associated with an embodiment;

FIG. 2A is a graph showing the dependence of ΔV_{fb} on the thickness of a carbon layer;

FIG. 2B is a graph showing the dependence of ΔV_{fb} on the thickness of the carbon layer;

FIG. 3 is a graph showing the dependence of the effective work function of TaCₓ on the composition thereof;

FIG. 4 is a graph showing the dependence of the effective work function of TaCₓ on the plane orientation thereof;

FIGS. 5 to 10 are sectional views showing a first process of manufacturing a semiconductor device associated with the embodiment;

FIGS. 11 to 22 are sectional views showing a second process of manufacturing a semiconductor device associated with the embodiment.

FIG. 23 is an energy band diagram for explaining a mechanism of V_{fb} modulation caused by providing the carbon layer between a gate electrode and a gate insulating film; and

FIG. 24 is an energy band diagram when (100)-oriented TaCₓ having a density of carbon atoms of 60 percent is used for a gate electrode.

### DETAILED DESCRIPTION OF THE INVENTION

The embodiments of the invention will be described in detail below with reference to the drawings.

To realize a CMIS device with a low threshold voltage, it is desirable that each gate electrode have an effective work function (Φ_{eff}) close to the following values:

the conduction band minimum of a silicon (around 4.1 electron volts) for N-channel MIS transistors; and the valence band maximum of the silicon (around 5.2 electron volts) for P-channel MIS transistors.

However, a metal having a high work function close to the valence band maximum (PMIS metal) has a problem that the effective work function on a high-k insulating film of e.g. HfSiON drops after annealing in a reducing atmosphere. Such problem interferes with a low threshold voltage because a step of annealing in the reducing atmosphere of about 400 to 450 degrees centigrade is essential for formation of an MIS transistor. For materialization of a dual metal gate CMIS structure, it is required to find a device structure which allows us to overcome the problem described above.

In other words, it is essential to introduce a dual metal gate technology for the purpose of enhancement of the performance of CMIS devices. However, for increasing the CMIS device performance, the instability of the work function Φ_{eff} of PMIS metal during annealing in the reducing atmosphere has been an obstacle.

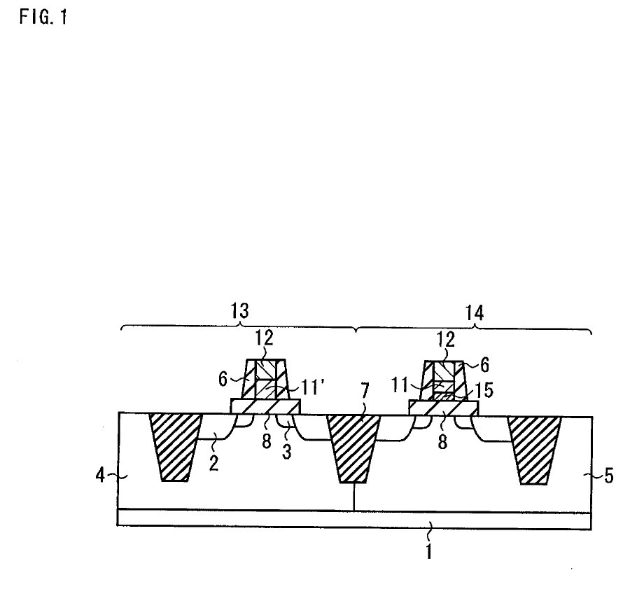

FIG. 1 is a sectional view showing an example of the arrangement of a semiconductor device associated with one embodiment of the invention.

As shown in FIG. 1, a P-type semiconductor region 4 and an N-type semiconductor region 5 are provided in a surface region of a semiconductor substrate 1 of silicon (Si). In the P-type and N-type regions, an N-channel MIS transistor 13 and a P-channel MIS transistor 14 are formed respectively. The P-type and N-type semiconductor regions 4 and 5 are a so-called well region, in each of which source and drain regions 2 and an extension region 3 are formed. Between the source and drain regions 2, a channel region which makes a current path with an arbitrary channel length is provided.

Gate insulating films 8 are formed on the surfaces of P-type semiconductor region 4 and N-type semiconductor region 5. A carbon (C) layer 15 of at least one monolayer and not more than 5 nanometers is formed on a surface of the gate insulating film 8 of the N-type semiconductor region 5. A gate electrode 11′ is formed on a surface of the gate insulating film 8 of the P-type semiconductor region 4. A gate electrode 11 is formed on a surface of a carbon (C) layer 15 of the N-type semiconductor region 5. Further, gate electrodes 12 made of e.g. a high-melting-point metal such as tungsten (W) or titanium nitride (TiN) may be formed on the gate electrode 11′ and gate electrode 11. According to the above arrangements, the N-channel MIS transistor 13 and P-channel MIS transistor 14 are formed. Now, it is noted that a device isolation region 7, as another constituent in FIG. 1, source and drain regions 2, extension regions 3 and gate-sidewall insulating films 6 are formed by a typical semiconductor process such as normal sputtering, CVD or RIE.

Aside from the source and drain regions 2 formed by an impurity diffusion layer as described above, the source and drain regions may be formed by a silicide layer. Thus, a so-called Schottky transistor may be formed.

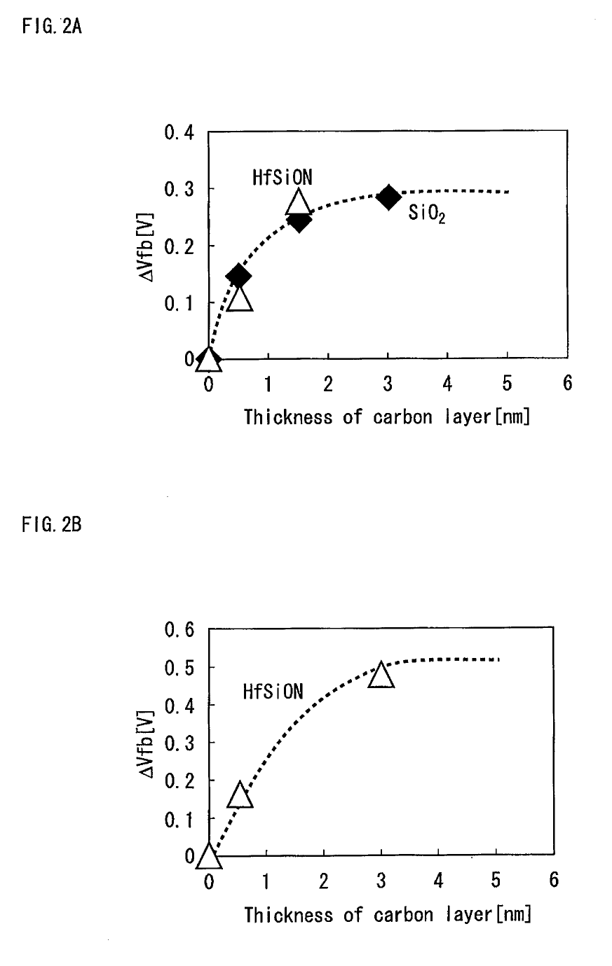

FIG. 2A is a graph showing the relation of the amount of modulation of a flat band voltage (V_{fb}) after annealing in a reducing atmosphere (H2/N2=3%, 450 degrees C., 30 min.) with the thickness of a carbon layer formed between the gate electrode and gate insulating film. The amount of V_{fb} modulation is a value derived by subtracting, from a V_{fb} value, the V_{fb} value when no carbon layer is formed between the gate electrode and gate insulating film. The drawing shows the results without 1000° C.-annealing (annealing in the reducing atmosphere was carried out). In this example, the gate electrode is made of tantalum carbide (hereinafter referred to as TaCₓ), and the gate insulating film is made of SiO₂ and HfSiON.

FIG. 2B is a graph showing the relation of the amount of modulation of a flat band voltage (V_{fb}) after 1000° C.-annealing (the annealing in the reducing atmosphere was carried out after 1000° C.-annealing) with the thickness of a carbon layer formed between the gate electrode and gate insulating film. In this example, the gate electrode is made of TaCₓ, and the gate insulating film is made of HfSiON.

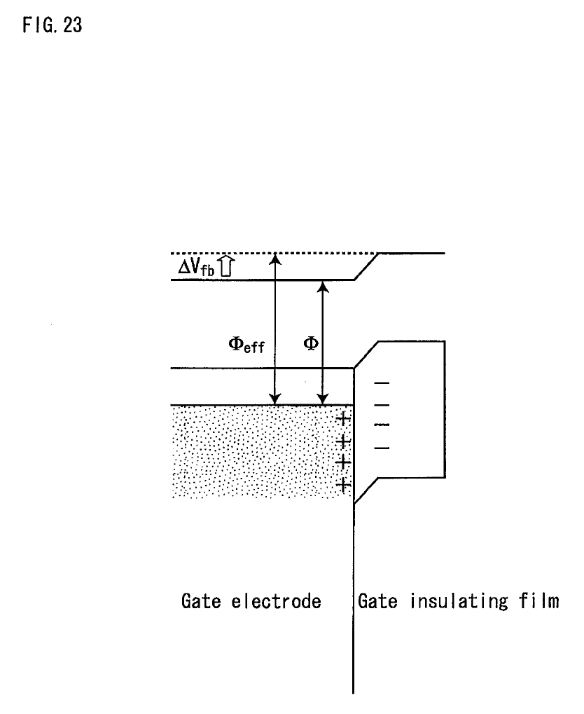

In any case, V_{fb} varies in the plus direction with an increase of the thickness of the carbon layer formed between the gate electrode and gate insulating film. A physical factor of this behavior is considered to be the formation of negative fixed charge in the gate insulating film owing to the carbon layer provided between the gate electrode and gate insulating film. FIG. 23 is an energy band diagram of a gate stack when negative fixed charge has been formed in the gate insulating film. As shown in FIG. 23, it is clear that the effective work function is modulated so as to rise, as the negative fixed charge is formed in the gate insulating film.

The value resulting from addition of the V_{fb} modulation amount to the work function of a metal used for the gate electrode is an effective work function Φ_{eff} of the gate electrode. Therefore, when advantage of this effect is taken, use of a metal having a work function of not less than 4.4 electron volts as the gate electrode 11 allows us to achieve a high Φ_{eff} suitable for PMISFETs. For instance, even in the case where a metal having a work function of 4.4 electron volts is used for the gate electrode 11, the carbon layer provided between the gate insulating film 8 and gate electrode 11 can materialize a Φ_{eff} not less than 4.7 electron volts. However, it is desirable that the work function of the gate electrode 11 be 4.9 electron volts or smaller. This is because such electrode has a good resistance to annealing in the reducing atmosphere.

Now, the resistance of the gate electrode of a PMISFET to annealing in the reducing atmosphere will be described here. A metal having a high work function close to the valence band maximum and put on a high-k insulating film of e.g. HfSiON has a problem that Φ_{eff} lowers after annealing in the reducing atmosphere. However, to form an MIS transistor, annealing in the reducing atmosphere at a temperature of about 400 to 450 degrees centigrade is essential. Therefore, because of such problem, a low threshold voltage cannot be achieved for a PMISFET even when a metal having a high work function is used for the gate electrode. In contrast, in this embodiment, the effective work function is made larger by putting a carbon layer at the interface of the gate electrode/gate insulating film as described above. As a result, an effective work function as required by PMISFETs can be achieved without a metal having a high work function close to the valence band maximum and low or no resistance to annealing in the reducing atmosphere, and therefore a low threshold voltage can be actualized.

In this embodiment, it is desirable that the thickness of the carbon layer formed on the gate insulating film 8 is nanometers or smaller. This is because when the thickness of the carbon layer is larger than 5 nanometers, the work function of the gate electrode 11 has little effect on Φ_{eff}. Thus, Φ_{eff} takes a value resulting from the addition of the V_{fb} modulation-effect described above to the work function of carbon, not to the work function of the gate electrode 11. To obtain the effect of the work function of the gate electrode 11 on Φ_{eff} with stability, it is desirable that the thickness of the carbon layer is 3 nanometers or smaller. It can be considered that V_{fb} is modulated when carbon exists on the gate insulating film 8. However, for stable modulation of V_{fb}, it is desirable that the thickness of the carbon layer is one monolayer or larger.

Also, It is acceptable that an upper part of the carbon layer includes a metal element made of the gate electrode 11, as a result of mixing a carbon layer and a gate electrode 11 in a thermal process of forming a transistor.

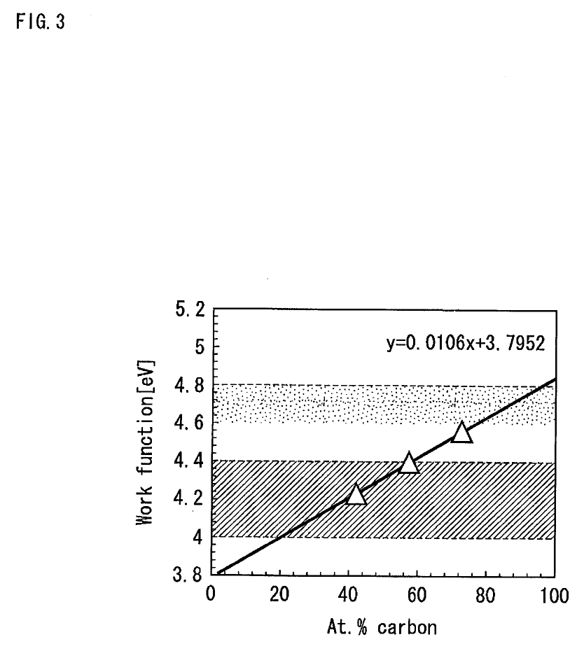

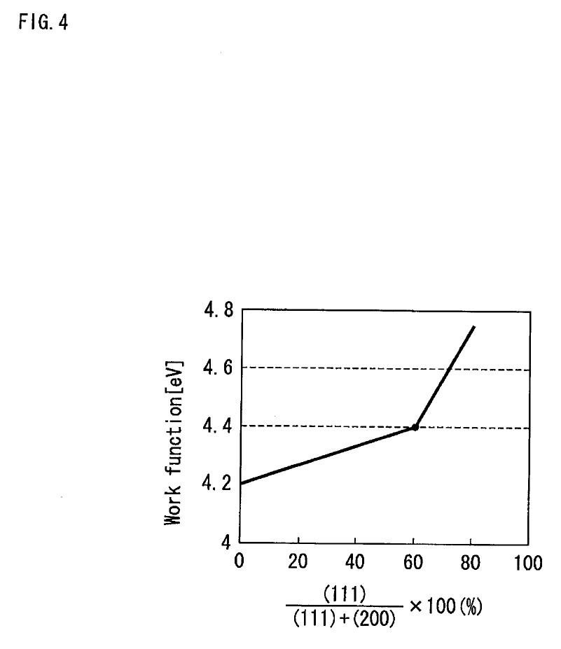

Further, it is desirable to use TaCₓ for the gate electrodes 11′ and 11. The work function of TaCₓ can be controlled by means of its composition or plane orientation, as shown in FIGS. 3 and 4. Therefore, the metal element used for the gate electrodes 11′ and 11 may be limited to one kind of metal, i.e. tantalum (Ta). When fewer metal elements are used for gate electrodes of a CMISFET, its manufacturing process can be prevented from being complicated correspondingly.

Specifically, in the case of controlling the work function by means of the composition, for instance, the following will suffice: using TaCₓ having a density of carbon atoms of not more than 60 percent for the gate electrode 11′; and using TaCₓ having a density of carbon atoms of not less than 60 percent for the gate electrode 11. This is because the work function of TaCₓ having a density of carbon atoms of not more than 60 percent is 4.4 electron volts or smaller, and the work function of TaCₓ having a density of carbon atoms of not less than 60 percent is 4.4 electron volts or larger, as shown in FIG. 3.

Incidentally, in this case, it is desirable, from the relation between the plane orientation and work function of the crystalline as described later, that the gate electrode 11′ be made of an amorphous substance, or the percentage given by the following expression be 60 percent or smaller.

TaC(111)plane/[TaC(111)plane+TaC(200)plane]

This is because as shown in FIG. 4, when the crystalline plane orientation percentage of TaC (111) plane in the direction of the film thickness given by the expression, TaC (111) plane [TaC (111) plane+TaC (200) plane], is 60 percent or smaller, the percentage of a portion that TaC (100) plane occupies, of a region of the gate electrode in contact with the insulating film, is larger and the (Φ_{eff} becomes 4.4 electron volts or smaller.

Further, in the case of taking advantage of the effect of V_{fb} modulation according to the plane orientation (see U.S. application Ser. No. 11/635,040), it is desirable to use, for the gate electrode 11′ and electrode 11, TaCₓ such that a density of carbon atoms of 60% and the crystalline plane orientation percentage of TaC(111) plane in a direction of the film thickness, which is given by the following expression, be smaller than 60 percent.

TaC(111)plane/[TaC(111)plane+TaC(200)plane]

In this case, even when the density of carbon atoms is 60 percent, Φ_{eff} smaller than 4.4 electron volts can be obtained for NMISFET. Further, in the case of carbon-rich TaCₓ having a density of carbon atoms larger than 60 percent, it is hard to crystallize, and therefore even when a carbon layer of a PMISFET mixes with TaCₓ of a gate electrode thereof in a process of forming a transistor, no TaC (100)-oriented plane is formed on a surface of a gate insulating film in a PMISFET and the plane orientation of the crystalline never lowers Φ_{eff} of the gate electrode in PMISFET. So, it is PMISFET Φ_{eff} that the sum of the work function 4.4 electron volts depending on the density of carbon atoms, and the amount of V_{fb} modulation according to the carbon layer. On this account, even if electrode 11′ and 11 are same TaCₓ, suitable Φ_{eff} are obtained for NMISFET and PMISFET.

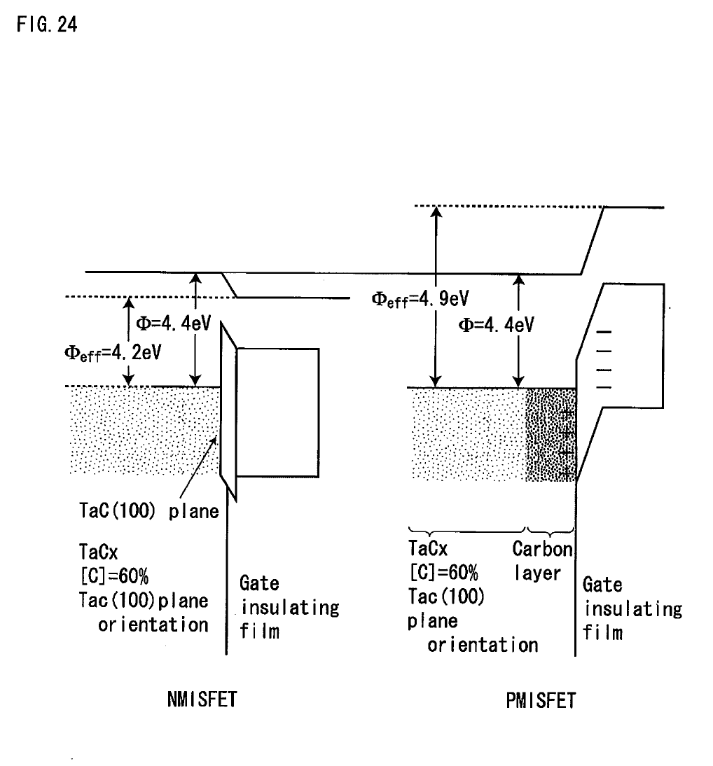

Now, an example will be explained with FIG. 24. In this example, (100)-oriented TaCₓ having a density of carbon atoms of 60 percent is used for gate electrodes of both MISFETs and a carbon layer is placed between the gate electrode and gate insulating film in PMISFET. FIG. 24 is a diagram of energy bands of an NMISFET and a PMISFET. The work function of TaCₓ having a density of carbon atoms of 60 percent is 4.4 electron volts. In regard to NMISFET, as (100) plane of TaCₓ is in contact with the gate insulating film, the effect of V_{fb} modulation coming from the plane orientation is developed in the minus direction. As a result, Φ_{eff} of NMISFET is shifted in the minus direction to 4.2 electron volts, from 4.4 electron volts which is the work function of the gate electrode as a bulk. In contrast, as for PMISFET, (100) plane of TaCₓ is out of contact with the gate insulating film, and therefore the effect of V_{fb} modulation coming from the plane orientation does not arise. However, the effect of V_{fb} modulation in the plus direction is developed by providing the carbon layer between the gate electrode and gate insulating film. In consequence, Φ_{eff} of PMISFET is shifted in the plus direction to 4.9 electron volts, from 4.4 electron volts which is the work function of the gate electrode as a bulk. The work function difference between both MISFETs is 0.7 electron volts, and a sufficiently low threshold voltage can be achieved.

When full use is made of the effect of V_{fb} modulation to design a semiconductor device as described above, the gate electrodes 11′ and 11 can be conformed to each other in composition. This is most desirable from the viewpoint of avoiding the increase in complexity of the manufacturing process because the gate electrodes 11′ and 11 can be processed collectively in this case.

However, this embodiment is not limited to when the gate electrodes 11 and 11 are formed of same materials. For example, in the case of using a metal material other than TaCₓ for a gate electrode of an N-channel transistor, it is conceivable to use, as a material having a work function of 4.4. electron volts or smaller, a metal such as Ti, Ta, Zr, Hf, V, Nb, Cr, Mo, W, La or Y, or boride, silicide, nitride or nitride silicide of a metal selected from among the metals described above. In the case of application to the Gate-First process, it is the most preferable, from the viewpoints of heat resistance and chemical stability, to use boride, nitride or nitride silicide of a metal such as Ti, Ta, Zr, Hf, V, Nb, Cr, Mo, W, La or Y.

What may be used as the gate insulating film are for example: insulating films of oxides of Ti, Hf, Zr and rare-earth metals including La, and oxide of a mixture of Ti, Hf, Zr and rare-earth metals; insulating films of silicate and aluminate of Ti, Hf, Zr and rare-earth metals including La, and the insulating films doped with nitrogen; and insulating films of Si₃N₄, Al₂O₃, Ta₂O₅, TiO₂, La₂O₃, CeO₂, ZrO₂, HfO₂, SrTiO₃ and Pr₂O₃, and the insulating films doped with nitrogen. Incidentally, in the case of using an insulating film of e.g. Hf silicate or Hf silicate doped with nitrogen, it is desirable from the viewpoint of the merit of leakage owing to the increase in dielectric constant that the following inequality hold.

Hf/(Hf+Si)≧0.5

In addition, the effect of the rise in V_{fb} by providing the carbon layer can be obtained regardless of whether or not 1000° C.-annealing has been carried out, as shown in FIGS. 2A and 2B. Therefore, the damascene process and Gate-First process are both applicable as manufacturing means. Incidentally, the effect of the rise in V_{fb} by providing the carbon layer was larger in the case where 1000° C.-annealing was carried out. Therefore, this embodiment is particularly suitable for Gate-First process.

Now, an example that a first manufacturing process including a damascene process is adopted as a process of manufacturing a semiconductor device associated with this embodiment will be described.

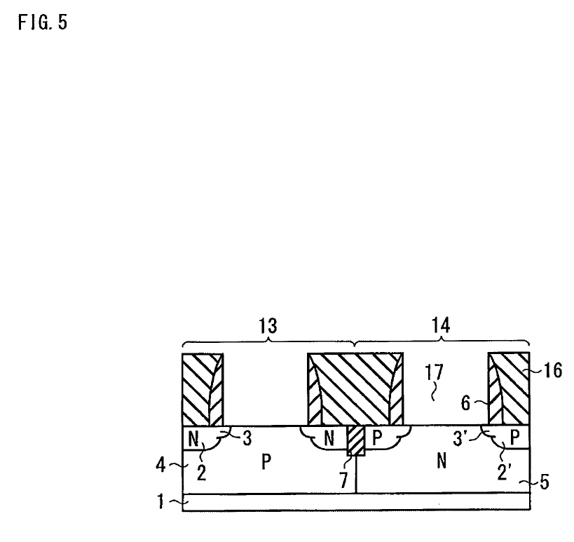

The manufacturing process shown by a set of FIGS. 5 to 10 is an example that the so-called replacement gate process is adopted, in which TaCₓ is used for the gate electrodes 11′ and 11.

First, a P-type semiconductor region 4 and an N-type semiconductor region 5, which are separated from each other by a device isolation layer 7 having an STI (Shallow Trench Isolation) structure, and will make well regions, are formed on a silicon semiconductor substrate 1 (hereinafter referred to as semiconductor substrate), as shown in FIG. 5. Second, dummy gates (not shown) are formed on the P-type semiconductor region 4 and N-type semiconductor region 5 respectively. Subsequently, an N-type impurity is implanted into the P-type semiconductor region 4 above the semiconductor substrate 1 by a well-known ion implantation method while the dummy gates are used as masks, thereby forming an N-type extension region 3. On the other hand, a P-type impurity is implanted into the N-type semiconductor region 5 to form a P-type extension region 3′.

Further, using the dummy gates and gate sidewall 6 as masks, an N-type diffusion layer 2 is formed by implantation of an N-type impurity into the P-type semiconductor region 4, and a P-type diffusion layer 2′ is formed by implantation of a P-type impurity into the N-type semiconductor region 5.

After that, the structure shown in FIG. 5 can be obtained by removing the dummy gates. As is clear from FIG. 5, respective grooves 17 are formed after removal of the dummy gates. It is noted that salicide layers may be formed on the diffusion layers 2 and 2′.

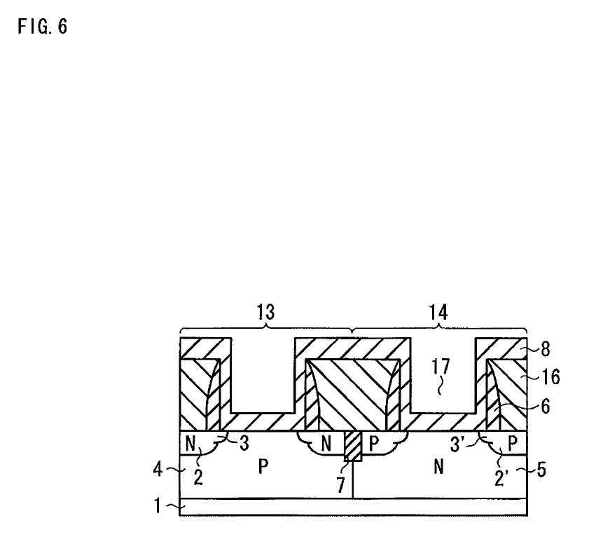

Subsequently, a gate insulating film 8 is formed as shown in FIG. 6.

What may be used as the gate insulating film 8 are, for example: insulating films of oxides of Ti, Hf, Zr and rare-earth metals including La, and a mixture thereof; insulating films of silicates and aluminates of Ti, Hf, Zr and rare-earth metals including La, and the silicate and aluminate films doped with nitrogen; and insulating films of Si₃N₄, Al₂O₃, Ta₂O₅, TiO₂, La₂O₃, CeO₂, ZrO₂, HfO₂, SrTiO₃ and Pr₂O₃, and the insulating films doped with nitrogen. While hafnium silicate doped with nitrogen is herein deposited by MOCVD (Metal Organic Chemical Vapor Deposition), it is just an example. Any deposition method may be used as long as it allows an insulating film to be formed along the bottom face and side face of each groove 17 after removal of the dummy gates, which may be e.g. ALD (Atomic Layer Deposition).

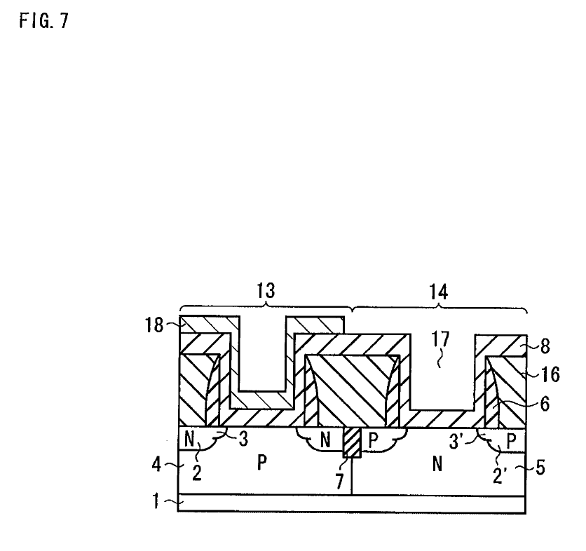

Then, a silicon oxide film is deposited on the gate insulating film 8 by e.g. LPCVD (Low Pressure Chemical Vapor Deposition), as shown in FIG. 7. Subsequently, the silicon oxide film is patterned by PEP (Photo Engraving Process) to form a mask 18 composed of a silicon oxide film on a surface of the gate insulating film 8 over the P-type semiconductor region 4.

Next, a carbon layer 15 having a thickness of one monolayer to 3 nanometers inclusive is formed on the gate insulating film 8 over the N-type semiconductor region 5 and the mask 18. The method for forming the carbon layer 15 is not particularly limited. For example, sputtering, CVD, and vapor deposition may be used as such film-forming method. However, the carbon layer 15 is to be removed by the lift-off method in a later step and as such, it is more preferable that the carbon layer 15 be formed by sputtering which offers an unfavorable step coverage at a stepped portion. In this embodiment, the carbon layer 15 having a thickness of 3 nanometers is formed by sputtering a carbon target.

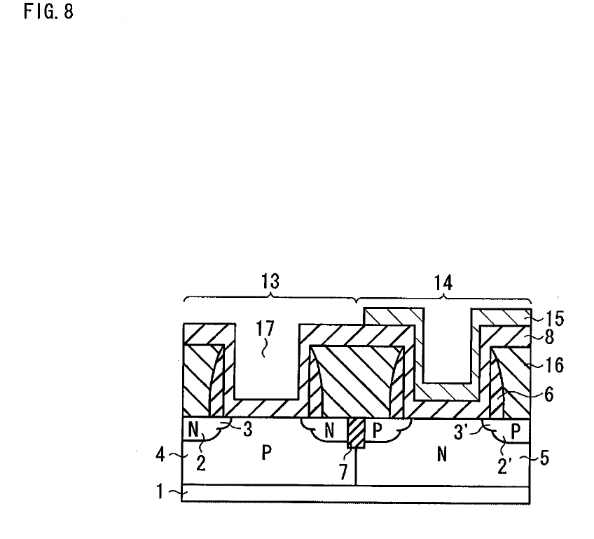

Subsequently, as shown in FIG. 8, the carbon layer 15 on the mask member 18 is removed by the lift-off method together with the mask member 18 shown in FIG. 7. For instance, when a dilute aqueous solution of hydrogen fluoride is used to remove the mask member 18 made of silicon oxide, a portion of the carbon layer 15 on the mask member 18 can be removed together at the same time. However, in this step, a portion of the carbon layer 15 over the N-type semiconductor region is not removed.

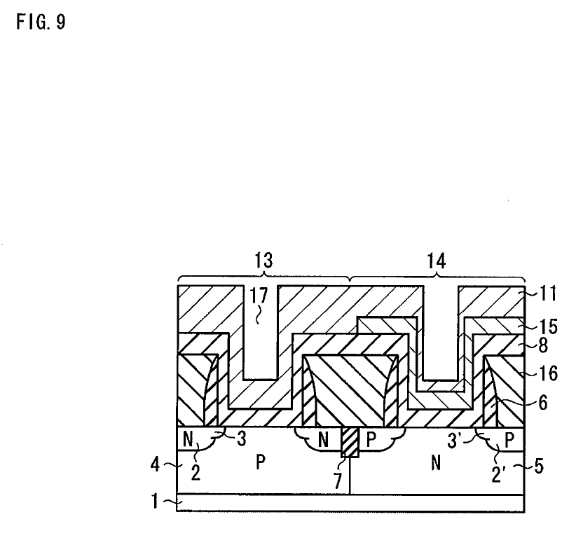

Then, a metal film, which will make the gate electrodes 11′ and 11, is formed on the gate insulating film 8 and the carbon layer 15 on the prospective N-channel and P-channel MIS transistors 13 and 14, as shown in FIG. 9.

In this embodiment, e.g. TaCₓ (hereinafter referred to as first TaCₓ) which has a carbon atom concentration of 60 to 80 atomic percent and a TaC (111) plane crystalline orientation percentage of not more than 60 percent with respect to a direction of the film thickness, is formed for the gate electrodes 11′ and 11, provided that the plane orientation percentage is derived from the following expression:

TaC(111)plane/[TaC(111)plane+TaC(200)plane]×100.

In this step, as for the prospective N-channel MIS transistor 13, an effective work function of not more than 4.4 electron volts can be achieved because of the effect of crystalline plane orientation owing the first TaCₓ partially in contact with the gate insulating film 8, and therefor a low threshold voltage can be realized. On the other hand, carbon-rich TaCₓ having a density of carbon atoms of not less than 60 percent is not crystallized, and therefore even when the carbon layer and first TaCₓ of the P-channel MIS transistor 14 are mixed in the step of forming the transistor, as to the prospective P-channel MIS transistor 14, no TaC (100)-oriented plane is formed on a surface of the gate insulating film 8. The work function of TaCₓ having a carbon atom concentration of 60 atomic percent or larger is 4.4 electron volts or larger. That is, for P-channel MIS transistors 14, the effective work function is 4.7 electron volts or larger because the effect of a rise of V_{fb} of +0.3 volts or larger, which stems from the carbon layer, is added to the work function of 4.4 electron volts or larger. Thus, a low threshold voltage can be achieved for a P-channel MIS transistor.

To form the above-described first TaCₓ with respect to the direction of the film thickness, it is effective to use a film-forming method such that formation of a TaC film progresses with Ta and C coexisting with each other. In the case of using CVD (Chemical Vapor Deposition), it is desirable to supply a tantalum source and a carbon source in parallel. In the case of using sputtering, it is desirable to perform simultaneous sputtering of a tantalum target and a carbon target.

In this embodiment, the first TaCₓ is formed to 50 nanometers in film thickness by sputtering a tantalum target and a carbon target in parallel. Then, the metal gate electrodes 12 are deposited while a metal material having a high melting point, such as tungsten (W) or titanium nitride (TiN), is filled into the respective narrowed grooves 17 on the gate electrodes 11 by e.g. MOCVD (Metal Organic Chemical Vapor Deposition).

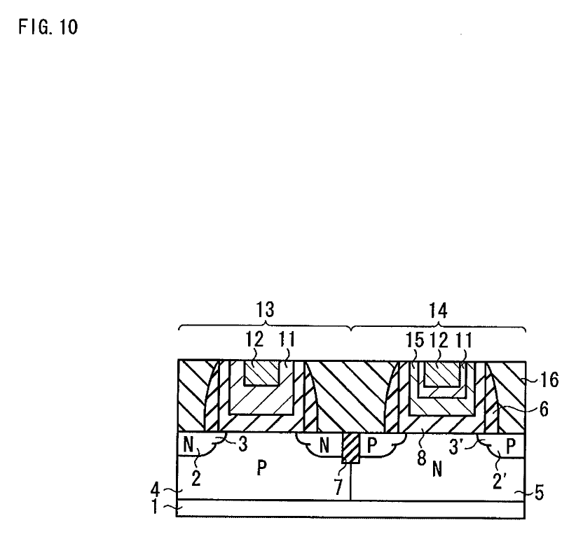

Next, a top of the resultant substrate is removed from its surface side by a typical CMP (Chemical Mechanical Polishing) process until the interlayer insulating film 16 is exposed while making flat the surface of the substrate. An N-channel MIS transistor and a P-channel MIS transistor, which are structured as shown in FIG. 10, are formed when the CMP process is completed.

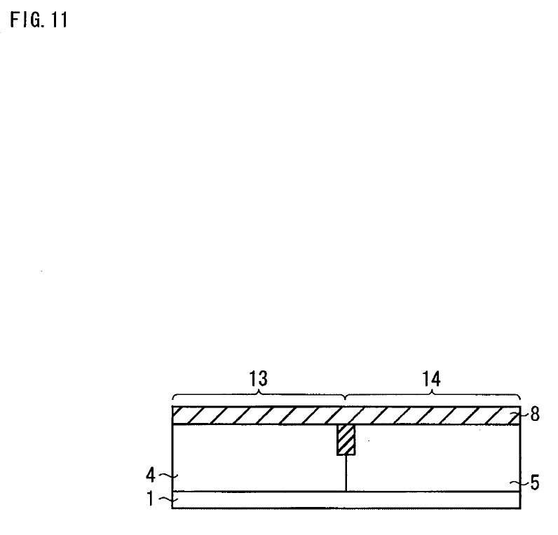

Subsequently, an example that a second manufacturing process including a Gate-First process shown by FIGS. 11 to 22 is adopted as a process of manufacturing a semiconductor device associated with this embodiment will be described.

First, a P-type semiconductor region 4 and an N-type semiconductor region 5, which are separated from each other by a device isolation layer 7 having an STI structure, are formed on a semiconductor substrate 1, followed by forming a gate insulating film 8 on the P-type and N-type semiconductor regions 4 and 5, as shown in FIG. 11.

What may be used as the gate insulating film are, for example: insulating films of oxides of Ti, Hf, Zr and rare-earth metals including La, and a mixture thereof; insulating films of silicates and aluminates of Ti, Hf, Zr and rare-earth metals including La, and the silicate and aluminate films doped with nitrogen; and insulating films of Si₃N₄, Al₂O₃, Ta₂O₅, TiO₂, La₂O₃, CeO₂, ZrO₂, HfO₂, SrTiO₃ and Pr₂O₃, and the insulating films doped with nitrogen. While hafnium silicate doped with nitrogen is herein deposited by MOCVD (Metal Organic Chemical Vapor Deposition), it is just an example. The deposition method may be e.g. MBE (Molecular Beam Epitaxy), ALD (Atomic Layer Deposition), or PVD (Physical Vapor Deposition).

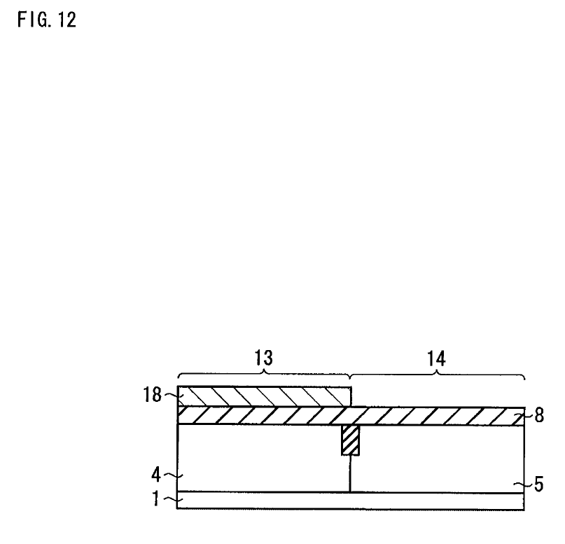

Then, a silicon oxide film is deposited on the gate insulating film 8 by e.g. LPCVD, as shown in FIG. 12. Subsequently, the silicon oxide film is patterned by PEP (Photo Engraving Process) to form a mask 18 composed of a silicon oxide film on a surface of the gate insulating film 8 over the P-type semiconductor region 4.

Next, a carbon layer 15 having a thickness of one monolayer to 5 nanometers inclusive is formed on the gate insulating film 8 over the N-type semiconductor region 5 and the mask 18. The method for forming the carbon layer 15 is not particularly limited. For example, sputtering, CVD, and vapor deposition may be used as such film-forming method. However, the carbon layer 15 is to be removed by the lift-off method as described later and as such, it is more preferable that the carbon layer 15 be formed by sputtering which offers an unfavorable step coverage at a stepped portion. In this embodiment, the carbon layer 15 having a thickness of 3 nanometers is formed by sputtering a carbon target.

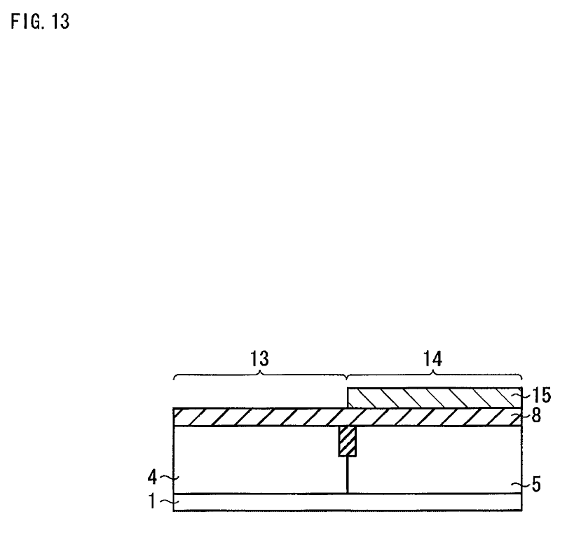

Subsequently, as shown in FIG. 13, the carbon layer 15 on the mask member 18 is removed by the lift-off method together with the mask member 18 shown in FIG. 7. For instance, when a dilute aqueous solution of hydrogen fluoride is used to remove the mask member 18 composed of a silicon oxide film, a portion of the carbon layer on the mask member 18 can be removed together at the same time. However, in this step, a portion of the carbon layer 15 over the N-type semiconductor region is not removed.

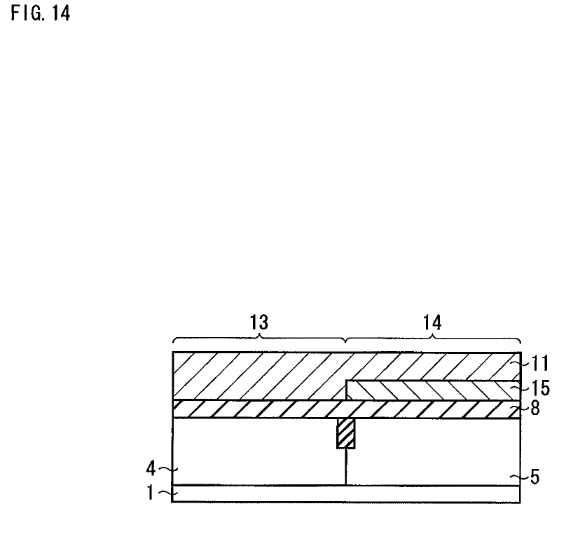

Then, gate electrodes 11′ and 11 are formed on the gate insulating film 8 and the carbon layer 15, as shown in FIG. 14. In this embodiment, TaCₓ (hereinafter referred to as second TaCₓ) which has a carbon atom concentration of 60 atomic percent and a TaC (111) plane crystalline orientation percentage of not more than 60 percent with respect to a direction of the film thickness, is formed for the gate electrodes 11′ and 11, provided that the plane orientation percentage is derived from the following expression:

TaC(111)plane/[TaC(111)plane+TaC(200)plane]×100.

In this step, as for the prospective N-channel MIS transistor 13, an effective work function of not more than 4.4 electron volts can be achieved because of the effect of crystalline plane orientation owing the second TaCₓ being partially in contact with the gate insulating film 8, and therefor a low threshold voltage can be realized. On the other hand, carbon-rich TaCₓ that the following inequality holds, is not crystallized:

C/Ta≧1.5.

Therefore, even when the carbon layer and second TaCₓ of the P-channel transistor are used in forming the transistor, as to the prospective P-channel transistor, no TaC (100)-oriented plane is formed on a surface of the gate insulating film 8. The work function of TaCₓ having a carbon atom concentration of 60 atomic percent or larger is 4.4 electron volts or larger. That is, as for P-channel transistors, a low threshold voltage can be achieved in the case of a P-channel transistor because the effect of a rise of V_{fb} of +0.3 volts or larger, which stems from the carbon layer, is added to the work function of 4.4 electron volts or larger.

To form the above-described second TaCₓ with respect to the direction of the film thickness, it is effective to use a film-forming method such that formation of a TaC film progresses with Ta and C coexisting with each other. In the case of using CVD, it is desirable to supply a tantalum source and a carbon source in parallel. In the case of using sputtering, it is desirable to perform simultaneous sputtering of a tantalum target and a carbon target. In this embodiment, the second TaCₓ is formed to 50 nanometers in film thickness by sputtering a tantalum target and a carbon target in parallel. Then, the metal gate electrodes 12 having a high melting point are deposited on the gate electrodes 11′ and 11 by e.g. MOCVD; and the metal gate electrodes are made of a metal material having a high melting point, such as tungsten (W) or titanium nitride (TiN).

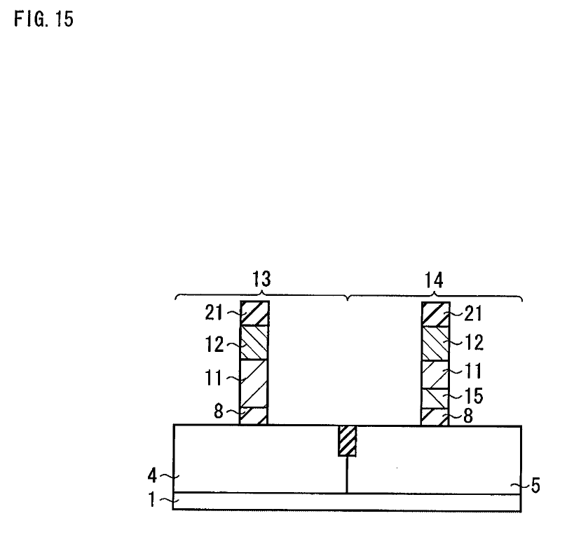

Thereafter, as shown in FIG. 15, a gate electrode resist pattern 21 is formed by a typical photolithography technique and etching technique, and a typical chlorine-based etching gas and a typical bromine-based etching gas are used to etch the resultant substrate to form the gate electrodes 11′ and 11, carbon layer 15 and gate insulating film 8. In this process, the P-channel MIS transistor and N-channel MIS transistor are identical to each other in their gate structure except that they are different in the presence or absence of the carbon layer having a remarkably small thickness of 3 nanometer or smaller. On this account, both of the transistors can be processed collectively.

Subsequently, the resist pattern 21 is removed by processing by an O₂-asher. After that, remaining resist, residue, etc., which cannot be removed completely by the processing by the O₂-asher, are chemically removed by a mixture of sulphuric acid and oxygenated water on an as-needed basis.

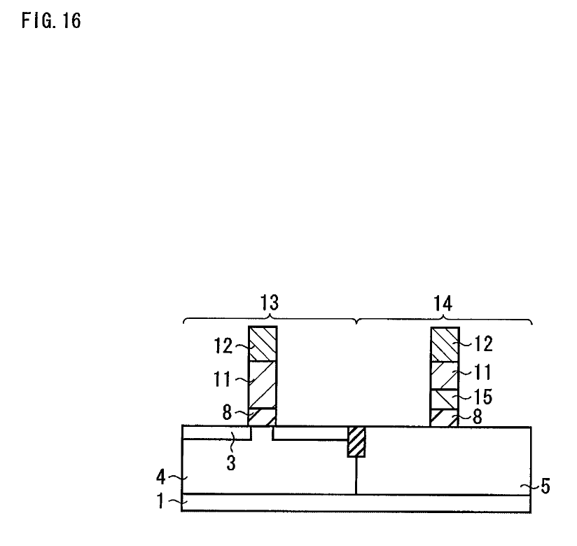

Next, as shown in FIG. 16, the top of the N-type semiconductor region 5 is covered with a resist (not shown), followed by ion implantation of an N-type impurity into the area of the P-type semiconductor region 4. Then, after having removed the resist over the N-type semiconductor region 5, an N-type extension region 3 is formed by spike annealing at a temperature of 1000 degrees centigrade or higher.

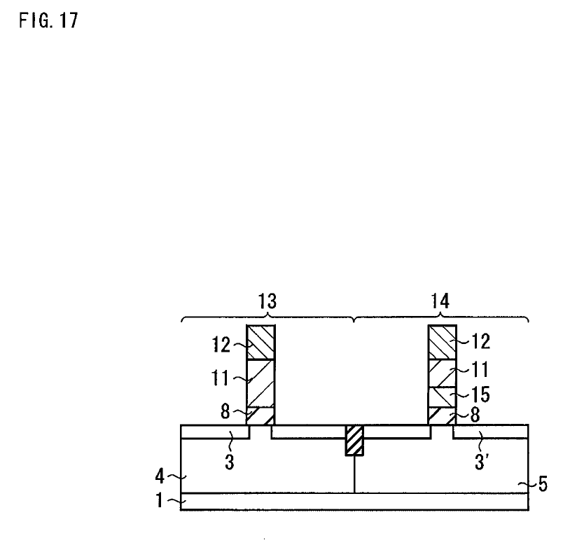

Subsequently, as shown in FIG. 17, the top of the P-type semiconductor region 4 is covered with a resist (not shown), followed by ion implantation of a P-type impurity into the area of the N-type semiconductor region 5. Then, after having removed the resist over the P-type semiconductor region 4, a P-type extension region 3′ is formed by spike annealing at a temperature of 1000 degrees centigrade or higher.

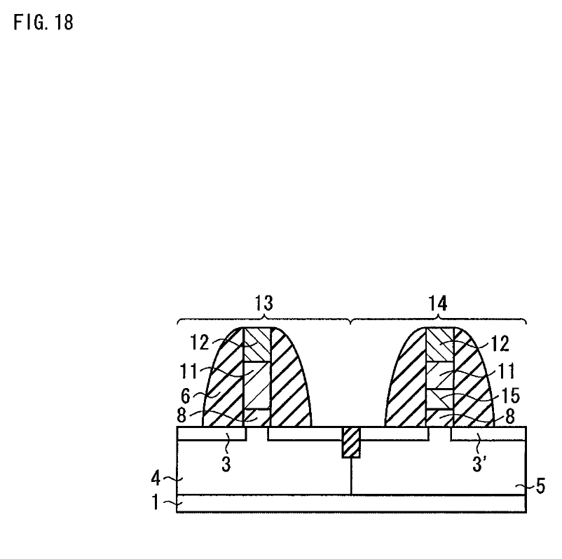

Thereafter, as shown in FIG. 18, a gate sidewall 6 is formed by a typical process. Specifically, an oxide film or the like is deposited on the whole surface of the substrate by CVD, followed by etching back the resultant substrate by e.g. RIE until the top surface of the gate electrode 12 is exposed.

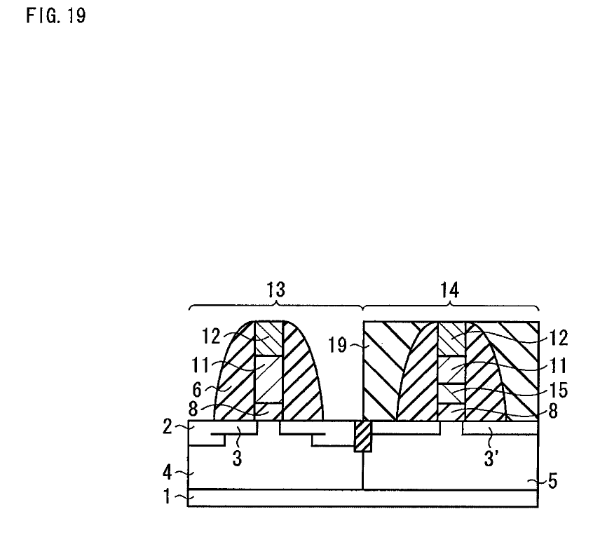

Then, as shown in FIG. 19, the top of the N-type semiconductor region 5 is covered with a resist 19, followed by implantation of an N-type impurity into the area of the P-type semiconductor region 4. Thus, an N-type doped region 2 is formed.

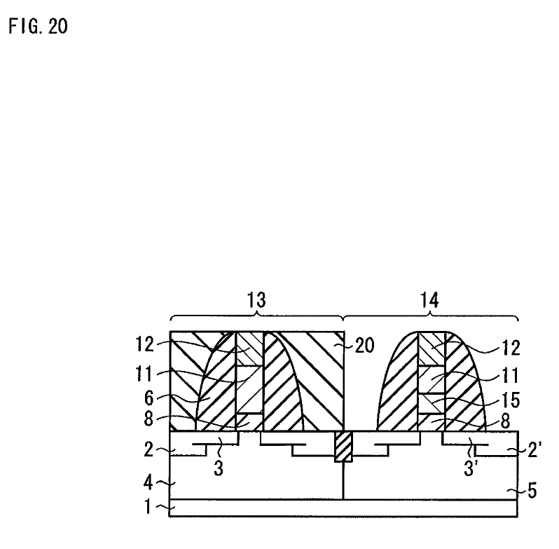

Next, as shown in FIG. 20, after having removed the resist 19 over the N-type semiconductor region 5, the top of the P-type semiconductor region 4 is covered with a resist 20, followed by implantation of a P-type impurity into the area of the N-type semiconductor region 5. Thus, a P-type doped region 2′ is formed.

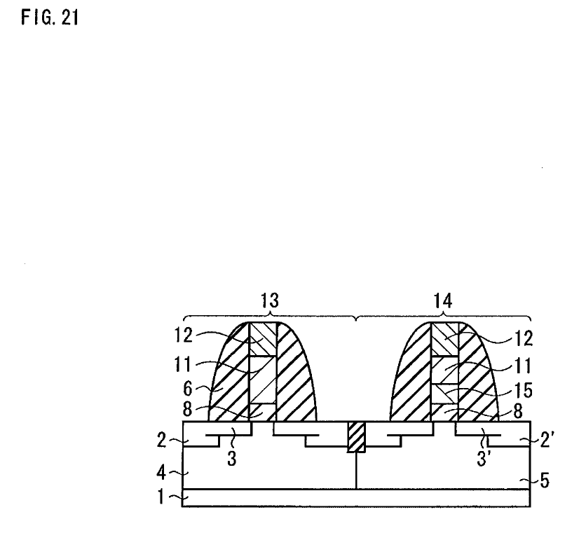

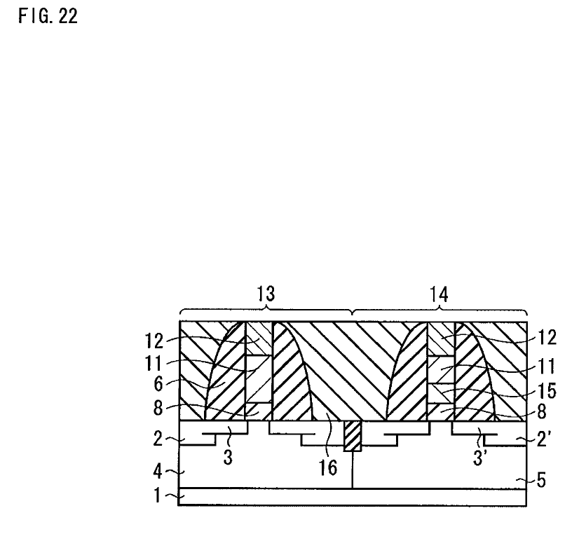

Then, as shown in FIG. 21, after having removed the resist 20 over the P-type semiconductor region 4, the N-type diffusion layer 2 and the P-type diffusion layer 2′ are completely activated by thermal processing at a temperature of 900 degrees centigrade or higher. After than, the substrate undergoes typical steps such as formation of an interlayer insulating film 16, and planarization, and then the structure as shown in FIG. 22 can be obtained.

It is explained about the case of the gate electrodes 11′ and 11 are formed of same materials, in first and second manufacturing process. However, the embodiment is not limited to this case. It is acceptable of course that the gate electrodes 11′ and 11 are formed of different materials. In this case, processing gate electrode materials for N-MISFET and P-MISFET are treated separately.

The embodiment is not limited to the above-described embodiments, and various changes and modifications of the constituents thereof may be made and embodied without departing from the subject matter of the invention. Especially, the effective work function required for gate electrodes varies depending on their applications and device generations. Even in such case, the invention can be arranged so as to adequately adapt to the effective work function required according to the individual cases. While in this embodiment, the descriptions have been presented taking, as one example of the substrate, a silicon semiconductor substrate, the invention is not so limited. The substrate may be any substrate as long as it has a semiconductor layer. That is, the invention can be applied to any kind of substrate including e.g. a substrate having a glass substrate and a semiconductor layer formed on the glass substrate like a liquid crystal substrate as long as it can withstand thermal processing that a common manufacturing process includes. Further in the case of forming a semiconductor device according to the invention by a low-temperature process, the invention can be applied to even a resin substrate.

What is claimed is:

1. A semiconductor device comprising:
a substrate;
an N-type semiconductor layer formed on the substrate;
first source/drain regions formed in the N-type semiconductor layer;
a first gate insulating film formed on the N-type semiconductor layer between the first source/drain regions;
a carbon layer formed on the first gate insulating film and having a thickness of 5 nanometers or smaller;
a first gate electrode formed on the carbon layer and including a metal;
a P-type semiconductor layer formed on the substrate;
second source/drain regions formed in the P-type semiconductor layer;
a second gate insulating film formed on the P-type semiconductor layer between the second source/drain regions; and
a second gate electrode formed on the second gate insulating film.

2. The semiconductor device according to claim 1, wherein the first gate electrode has a work function of 4.9 electron volts or smaller on a side close to the first gate insulating film.

3. The semiconductor device according to claim 1, wherein the first gate electrode has a work function of 4.4 to 4.9 electron volts inclusive, on a side close to the first gate insulating film.

4. The semiconductor device according to claim 1, wherein the second gate electrode has an effective work function of 4.4 electron volts or smaller, on a side close to the second gate insulating film.

5. The semiconductor device according to claim 1, wherein a side of the first gate electrode, being close to the first gate insulating film, is formed of tantalum carbide; and
a side of the second gate electrode, being close to the second gate insulating film, is formed of tantalum carbide.

6. The semiconductor device according to claim 5, wherein the tantalum carbide of the first gate electrode has a concentration of carbon atoms of 60 or larger atomic percent.

7. The semiconductor device according to claim 5, wherein the tantalum carbide of the second gate electrode has a concentration of carbon atoms of 60 atomic percent or smaller.

8. The semiconductor device according to claim 5, wherein the second gate electrode has a value of 60 percent or smaller as a TaC (111) plane orientation percentage with respect to a thickness direction, on the side close to the second gate insulating film, and
the value is derived from:
TaC(111)plane/[TaC(111)plane+TaC(200)plane]×100.

9. The semiconductor device according to claim 1, wherein the first and second gate insulating films are formed of HfSiON.

10. The semiconductor device according to claim 1, wherein the first and second gate insulating films are formed of hafnium oxide.

11. The semiconductor device according to claim 1, wherein said device comprises an NMISFET and a PMISFET.

12. The semiconductor device according to claim 1, wherein said carbon layer has a thickness of about one monolayer.

13. A method for manufacturing a semiconductor device, comprising:
forming a P-type semiconductor region and an N-type semiconductor region on a semiconductor substrate, the P-type and N-type semiconductor regions being isolated from each other;
forming a first dummy gate on the P-type semiconductor region and a second dummy gate on the N-type semiconductor region;
forming first source/drain regions in the P-type semiconductor region on opposite sides of the first dummy gate;
forming second source/drain regions in the N-type semiconductor region on opposite sides of the second dummy gate;
forming an insulating layer on side portions of the first and second dummy gates covering the first and second source/drain regions;
removing the first and second dummy gates thereby to form first and second grooves in the insulating layer;
forming first and second gate insulating layers on bottom portions of the first and second grooves;
forming a carbon layer which covers a top of the second gate insulating film, but not a top of the first gate insulating film; and
forming first and second gate electrode materials including a metal on the first gate insulating film and carbon layer.

14. The method according to claim 13, wherein the second gate electrode material has a work function of 4.9 electron volts or smaller.

15. The method according to claim 131 wherein the second gate electrode material has a work function of 4.4 to 4.9 electron volts inclusive.

16. The method according to claim 13, wherein the gate electrode material is a tantalum carbide.

17. The method according to claim 13, wherein the carbon layer is formed by sputtering.

18. The method according to claim 13, comprising forming said carbon layer to a thickness in a range of about one monolayer to 5 nanometers.

19. A method for manufacturing a semiconductor device, comprising:
forming a P-type semiconductor region and an N-type semiconductor region on a semiconductor substrate, the P-type and N-type semiconductor regions being isolated from each other;
forming a first gate insulating film on the P-type semiconductor region and a second gate insulating film on the N-type semiconductor region;
forming a carbon layer which covers a top of the second gate insulating film, but not a top of the first gate insulating film;
forming first and second gate electrode materials including a metal on the first gate insulating film and carbon layer;
etching the carbon layer and the gate electrode material, thereby to form a first gate electrode including the gate electrode material, and to form a second gate electrode including the gate electrode material and carbon layer; and
forming first source/drain regions in the P-type semiconductor region; and
forming second source/drain regions in the N-type semiconductor region.

20. The method according to claim 19, wherein the second gate electrode material has a work function of 4.9 electron volts or smaller.

21. The method according to claim 19, wherein
the second gate electrode material has a work function of 4.4 to 4.9 electron volts inclusive.

22. The method according to claim 19, wherein the gate electrode material is tantalum carbide.

23. The method according to claim 19, wherein the carbon layer is formed by sputtering.

24. The method according to claim 19, comprising forming said carbon layer to a thickness in a range of about one monolayer to 5 nanometers.
